(19) United States
(12) Patent Application Publication
(10) Pub. No.: US 2021/0183761 A1
(43) Pub. Date: Jun. 17, 2021

(54) LINE PATTERNING IN INTEGRATED CIRCUIT DEVICES

(71) Applicant: Intel Corporation, Santa Clara, CA (US)

(72) Inventors: Reken Patel, Portland, OR (US); Mohit K. Haran, Hillsboro, OR (US); Jeremy J. Guttman, Portland, OR (US); Shyam B. Kadali, Portland, OR (US); Ruth Amy Brain, Portland, OR (US); Seyedhamed M Barghi, North Plains, OR (US); Zhenjun Zhang, Portland, OR (US); James Jeong, Beaverton, OR (US); Robert M. Bigwood, Hillsboro, OR (US); Charles Henry Wallace, Portland, OR (US)

(73) Assignee: Intel Corporation, Santa Clara, CA (US)

(21) Appl. No.: 16/713,867

(22) Filed: Dec. 13, 2019

(51) Int. Cl. H01L 23/528; H01L 21/768; H01L 21/311

(52) U.S. Cl. CPC H01L 23/528; H01L 21/31144; H01L 21/76816

(57) ABSTRACT

Disclosed herein are line patterning techniques for integrated circuit (IC) devices, as well as related devices and assemblies In some embodiments, a patterned line region of an IC device may include: a first conductive line; a second conductive line parallel to the first conductive line; a conductive bridge between the first conductive line and the second conductive line, wherein the conductive bridge is coplanar with the first conductive line and the second conductive line; and pitch-division artifacts.

### BACKGROUND

In many areas of electronics, there exists a drive to decrease the size of integrated circuit (IC) devices. However, the practical constraints of manufacturing technology may limit the size and arrangement of features that can be fabricated in such devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIGS. 1A and 1B are various views of an integrated circuit (IC) device including a patterned line region, in accordance with various embodiments.

FIGS. 2A-2B, 3A-3B, 4A-4B, 5A-5B, 6A-6B, 7A-7B, 8A-8B, 9A-9B, 10A-10B, 11A-11B, 12A-12B, 13A-13B, 14A-14B, and 15A-15B illustrate stages in an example process for manufacturing a patterned line region in an IC device, in accordance with various embodiments.

FIG. 16 is a top view of a patterned line region in an IC device, in accordance with various embodiments.

FIG. 17 is a top view of a wafer and dies that may include one or more patterned line regions, in accordance with any of the embodiments disclosed herein.

FIG. 18 is a side, cross-sectional view of an IC device that may include one or more patterned line regions, in accordance with any of the embodiments disclosed herein.

FIG. 19 is a side, cross-sectional view of an IC package that may include one or more patterned line regions, in accordance with various embodiments.

FIG. 20 is a side, cross-sectional view of an IC device assembly that may include one or more patterned line regions, in accordance with any of the embodiments disclosed herein.

FIG. 21 is a block diagram of an example electrical device that may include one or more patterned line regions, in accordance with any of the embodiments disclosed herein.

### DETAILED DESCRIPTION

Disclosed herein are line patterning techniques for integrated circuit (IC) devices, as well as related devices and assemblies In some embodiments, a patterned line region of an IC device may include: a first conductive line; a second conductive line parallel to the first conductive line; a conductive bridge between the first conductive line and the second conductive line, wherein the conductive bridge is coplanar with the first conductive line and the second conductive line; and pitch division artifacts.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

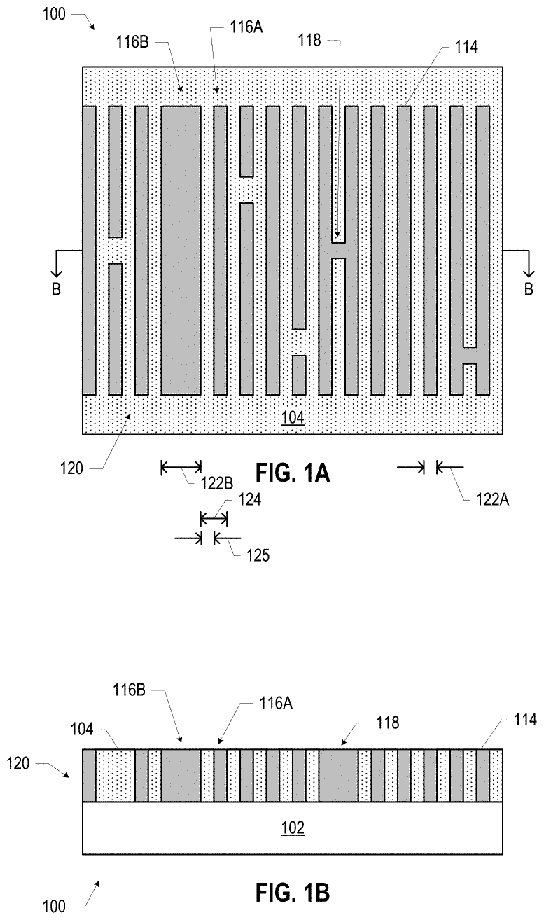

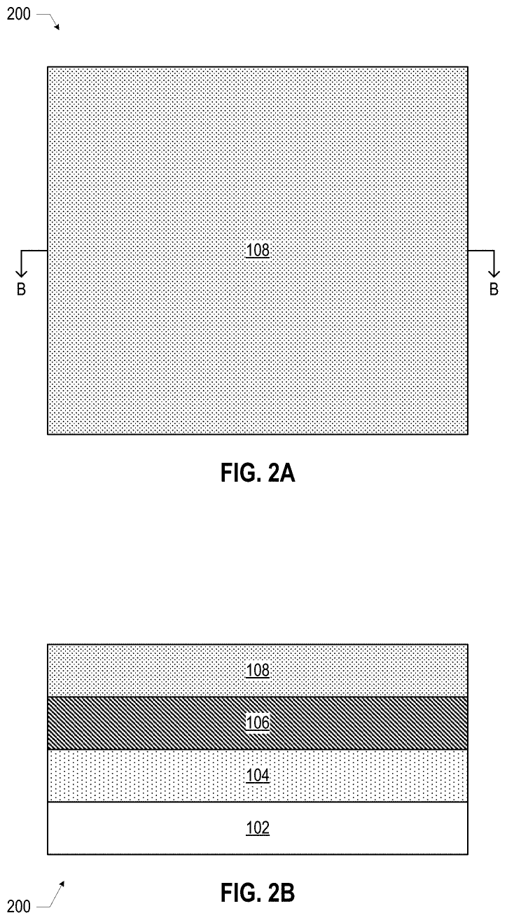

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. When used to describe a range of dimensions, the phrase “between X and Y” represents a range that includes X and Y. For convenience, the phrase “FIG. 1” may be used to refer to the collection of drawings of FIGS. 1A-1B, the phrase “FIG. 2” may be used to refer to the collection of drawings of FIGS. 2A-2B, etc.

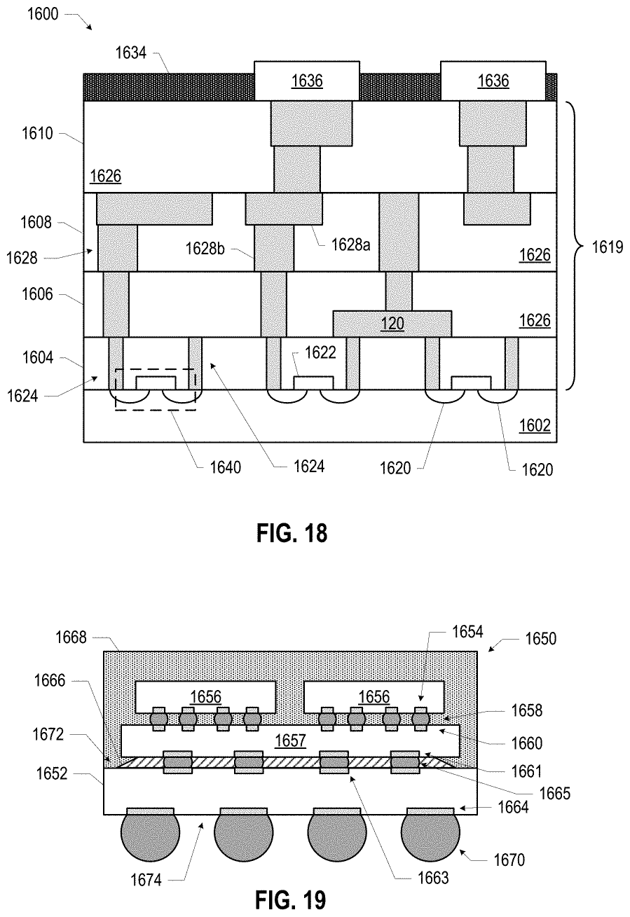

FIG. 1 illustrates a portion of an IC device 100 including a patterned line region 120. In particular, FIG. 1A is a top view of the portion of the IC device 100, and FIG. 1B is a side, cross-sectional view through the section B-B of FIG. 1A. All of the “A” and “B” sub-figures in the accompanying drawings share the perspective of the cross-sectional views of FIGS. 1A and 1B, respectively. The patterned line region 120 may be part of a die interconnect layer (e.g., any of the interconnect layers discussed below with reference to the metallization stack 1619 of FIG. 18), part of a metallization layer in an interposer (e.g., a silicon interposer or an embedded multi-die interconnect bridge (EMIB)), or in any other suitable setting. The patterned line region 120 may be disposed on a support 102; in some embodiments, the support 102 may include other interconnect layers and/or one or more device layers (e.g., the device layer 1604 discussed below with reference to FIG. 18).

The patterned line region 120 may include multiple parallel conductive lines 116 in a dielectric material 104. In some embodiments, the dielectric material 104 may be an interlayer dielectric (ILD), such as silicon oxide or any other suitable dielectric material. The conductive lines 116 may include any suitable material(s) 114, such as a metal (e.g., copper, tungsten, titanium, cobalt, tantalum, a combination thereof, etc.). In some embodiments, a conductive line 116 may include multiple layers of different materials; for example, a conductive line 116 may include a layer of tantalum nitride/tantalum (TNT) or titanium nitride between the adjacent dielectric material 104 and a fill metal (e.g., copper) to mitigate diffusion of the fill metal into the dielectric material 104. In some embodiments, cobalt may be be used as a liner material for conductive lines 116.

In the patterned line region 120, various ones of the lines 116 may have different widths 122. For example, the patterned line region 120 may include narrow lines 116A having a width 122A that is less than a width 1228 of wide lines 1168. The terms “narrow” and “wide” are used in this disclosure in a relative sense; a wide line 1168 has a greater width 1228 than the width 122A of a narrow line 116A. In particular, the patterned line region 120 may include one or more arrangements in which a wide line 1168 is adjacent to a narrow line 116A. In such arrangements, the narrow line 116A may be spaced apart from the wide line 1168 by an inter-line distance 125 that, in some embodiments, is less than 20 nanometers. In some embodiments, the width 122A of the narrow line 116A may be less than 20 nanometers. In some embodiments, the pitch 124 from the narrow line 116A to the wide line 1168 (the sum of the inter-line distance 125 and the width 122A) may be less than 40 nanometers; more generally, the pitch 124 between adjacent narrow lines 116A may also be less than 40 nanometers. In some embodiments, the width 1228 of a wide line 1168 may be at least two times greater than the width 122A (e.g., at least or approximately three times greater, at least or approximately five times greater, etc.). Although FIG. 1 (and others of the accompanying drawings) depicts a single wide line 1168 in the patterned line region 120, this is simply for ease of illustration, and any patterned line region 120 may include one or more wide lines 1168. Further, different wide lines 1168 in a patterned line region 120 may have different widths (e.g., one wide line 1168 may have a width 1228 that is approximately three times greater than the width 122A of a narrow line 116A, while another wide line 1168 may have a width 1228 that is approximately five times greater than the width 122A of a narrow line 116A).

A fine-pitch patterned line region 120 including an adjacent narrow line 116A and wide line 1168, like that illustrated in FIG. 1, cannot be fabricated using conventional line patterning techniques. Some such conventional techniques, such as lithographic patterning, may be able to fabricate a wide line adjacent to a narrow line, but cannot do so at a fine pitch (e.g., 40 nanometers or less for 193 nanometer immersion lithography). Other such conventional techniques, such as pitch division (discussed further below), can achieve a fine pitch between adjacent lines, but cannot also achieve a wide line adjacent to a narrow line. FIGS. 2-15, discussed below, illustrate various techniques for fabricating a fine-pitch patterned line region including an adjacent narrow line and wide line, and thus enable the fabrication of IC devices having arrangements of conductive lines that were not previously achievable.

The patterned line region 120 of FIG. 1 may also include inter-line bridges 118 between various ones of the adjacent lines 116; FIG. 1 illustrates two such inter-line bridges 118 (also referred to herein simply as “bridges 118”). The bridges 118 may be formed of the same material(s) as the conductive lines 116, and may electrically bridge two or more adjacent lines 116; in some embodiments, the bridges 118 may be oriented substantially perpendicular to the lines 116 being bridged. Although FIG. 1 (and others of the accompanying drawings) depict a bridge 118 as electrical connecting only two adjacent lines 116, this is simply for ease of illustration, and a bridge 118 may electrically connect two or more adjacent lines 116. Further, any pair of adjacent lines 116 may be electrically coupled by bridges 118 and more than one location along the length of the lines 116, as desired. In embodiments that include a wide line 1168 adjacent to a narrow line 116A, as discussed above, a bridge 118 may couple the narrow line 116A and the wide line 1168, or multiple wide lines 1168, as desired.

A fine-pitch patterned line region 120 including a bridge 118 between adjacent lines 116, like that illustrated in FIG. 1, cannot be fabricated using conventional line patterning techniques. Some such conventional techniques, such as lithographic patterning may be able to fabricate bridges between two adjacent lines, but cannot do so at a fine pitch (e.g., 40 nanometers or less). Other such conventional techniques, such as pitch division (discussed further below), can achieve a fine pitch between adjacent lines, but cannot also achieve bridges between adjacent lines. FIGS. 2-15, discussed below, illustrate various techniques for fabricating a fine-pitch patterned line region including bridges between adjacent lines, and thus enable the fabrication of IC devices having arrangements of conductive lines that were not previously achievable. In particular, the use of bridges 118 may enable two-dimensional routing in a fine-pitch interconnect layer (e.g., paths that can extend in an x-direction when lines are otherwise patterned to extend in a y-direction); conventionally, any such routing would require the use of an additional interconnect layer. Although FIG. 1 illustrates a patterned line region 120 that includes both adjacent narrow/wide lines at fine pitch and bridges between fine-pitched adjacent lines, a patterned line region 120 in accordance with the present disclosure may include only one of these types of arrangements, as desired.

FIGS. 2-15 illustrate stages in an example process for manufacturing a patterned line region 120 in an IC device 100, in accordance with various embodiments. Although the operations of the process illustrated in FIGS. 2-15 are depicted with reference to fabricating the particular embodiment of the IC device 100 illustrated in FIG. 1, this process may be used to form IC devices 100 including patterned line regions 120 including different numbers and arrangements of adjacent narrow/wide lines at fine pitch and/or bridges between fine-pitched adjacent lines.

FIG. 2 depicts an assembly 200 including a support 102, a dielectric material 104, a hardmask 106, and a pitch-division backbone material 108 (also referred to herein simply as a “backbone material 108”). The support 102 and the dielectric material 104 may take any suitable form (e.g., the form of any of the embodiments of these elements disclosed herein), and the thickness of the dielectric material 104 may be equal to the desired height of the conductive lines 116. The hardmask 106 may include any suitable materials (e.g., silicon nitride, carbon-doped silicon oxide, or carbon-doped silicon oxynitride). In some embodiments, the hardmask 106 may be provided by multiple layers of hardmasks having various material compositions and properties, as desired. The backbone material 108 may include any suitable dielectric material conventionally used as a backbone material in pitch-division fabrication techniques (e.g., pitch-halving or pitch-quartering). The assembly 200 may be fabricated using any suitable manufacturing techniques (e.g., various deposition and/or planarization techniques).

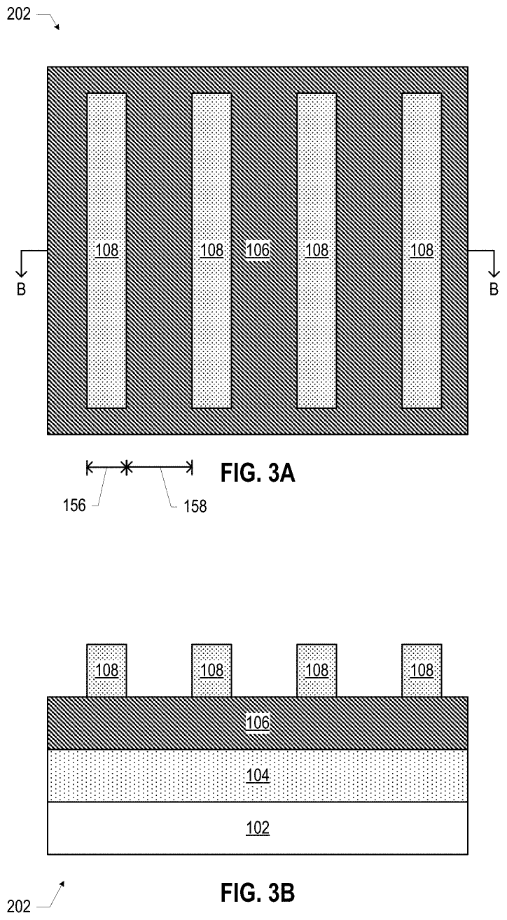

FIG. 3 depicts an assembly 202 subsequent to patterning the backbone material 108 of the assembly 200 (FIG. 2) into ribs. The ribs of backbone material 108 may have a width 156 and an inter-rib spacing 158; as will be demonstrated further below, the width 122 and the inter-line distance 125 may depend on the width 156 and the inter-rib spacing 158. In some embodiments, the width 156 may be approximately equal to three times the width 122A of the narrow lines 116A, and the inter-rib distance 158 may be approximately equal to five times the width 122A of the narrow lines 116A. The backbone material 108 may be patterned using a lithographic technique.

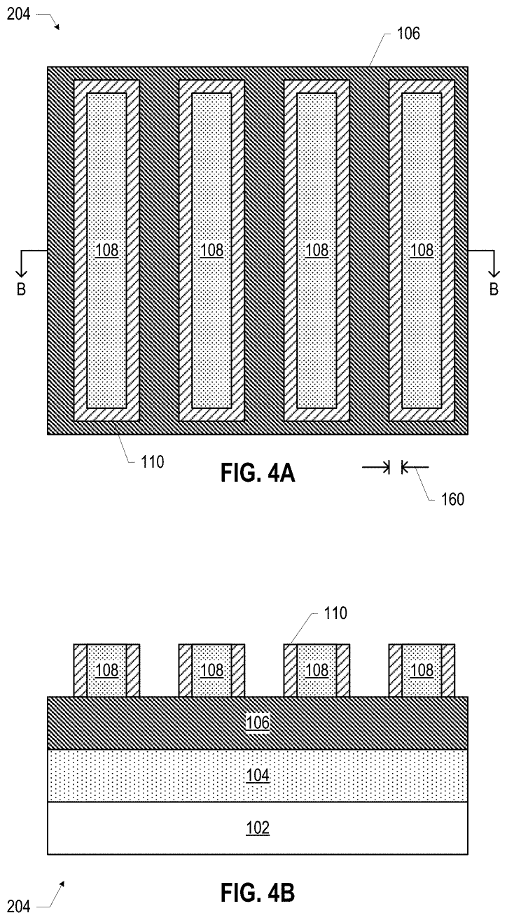

FIG. 4 depicts an assembly 204 subsequent to forming first spacers 110 on side faces of the ribs of backbone material 108 of the assembly 202 (FIG. 3). The first spacers 110 may be formed by conformally depositing a layer of the material of the first spacers 110 over the assembly 202 (FIG. 3), then directionally etching the result “downward” (perpendicularly to the surface of the hardmask 106) to remove the material of the first spacers 110 on the “horizontal” faces of the backbone material 108 and the hardmask 106, as known in the art. The width 160 of the first spacers 110 may be less than 40 nanometers (e.g., between 15 nanometers and 30 nanometers); in some embodiments, the width 160 of the first spacers 110 may be equal to approximately one-half the pitch 124.

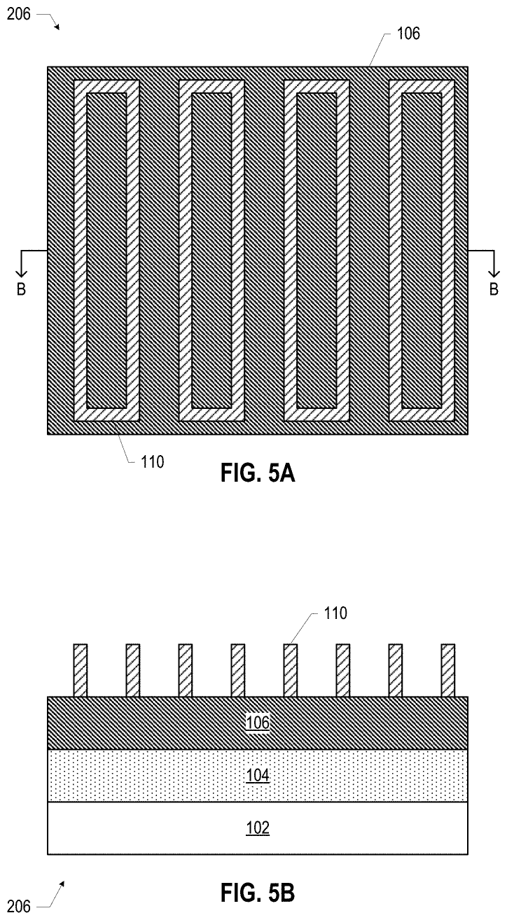

FIG. 5 depicts an assembly 206 subsequent to removing the backbone material 108 from the assembly 204 (FIG. 4). The backbone material 108 may be removed by a suitable selective etch, leaving the first spacers 110.

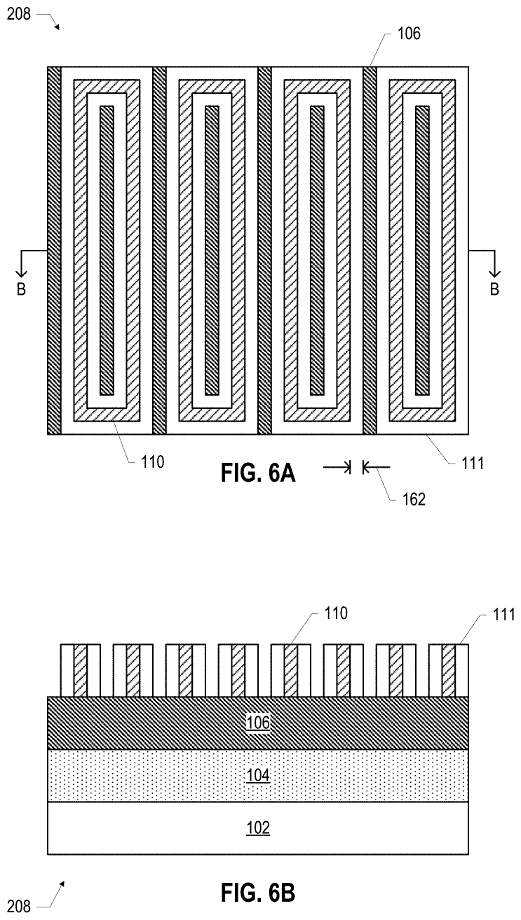

FIG. 6 depicts an assembly 208 subsequent to forming second spacers 111 on side faces of the first spacers 110 of the assembly 206 (FIG. 5). The second spacers 111 may be formed using the same technique discussed above with reference to the formation of the first spacers 110. The width 162 of the second spacers 111 may be less than 40 nanometers (e.g., between 50 nanometers and 30 nanometers); in some embodiments the width 162 of the second spacers 111 may be equal to approximately one-half the pitch 124.

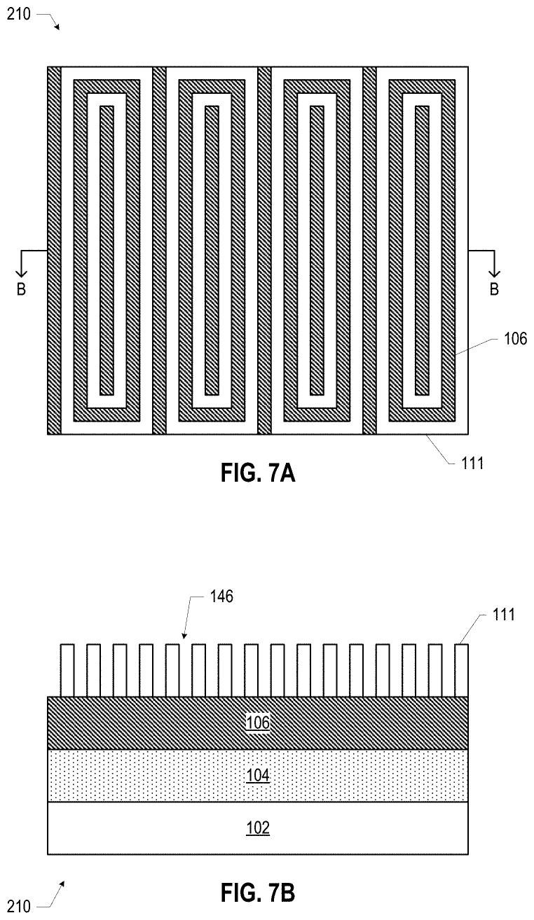

FIG. 7 depicts an assembly 210 subsequent to removing the first spacers 110 from the assembly 208 (FIG. 6). The first spacers 110 may be removed by a suitable selective etch, leaving the second spacers 111 and trenches 146 therebetween.

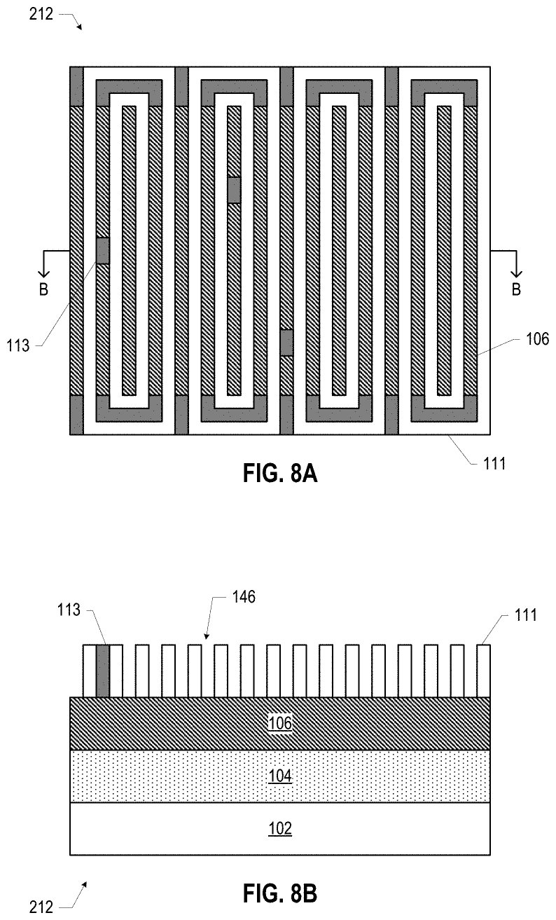

FIG. 8 depicts an assembly 212 subsequent to depositing a plug material 113 in selective locations in the trenches 146 of the assembly 210 (FIG. 7). As will be demonstrated further below, the locations of the second spacers 111 generally correspond to the locations of the dielectric material 104 in the patterned line region 120; the plug material 113 may be deposited around the second spacers 111 in locations where additional dielectric material 104 is desired in the patterned line region 120. For example, plug material 113 disposed between two elongated sections of the second spacers 111 may correspond to a “cut” in a line 116, while plug material 113 disposed proximate to the shorter sections of the second spacers 111 may correspond to an “end” of a line 116. The plug material 113 may be selectively deposited using any suitable technique, and the result may be planarized (e.g., using a chemical mechanical polishing (CMP) technique), as suitable.

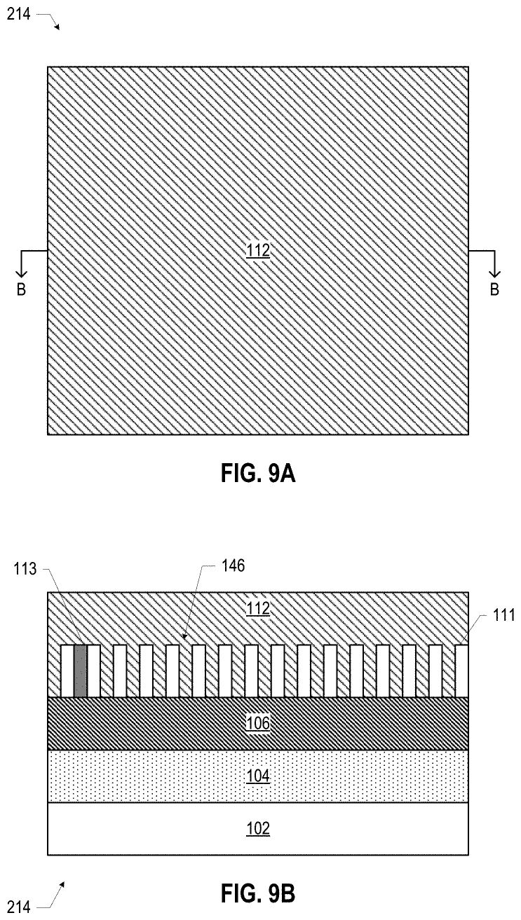

FIG. 9 depicts an assembly 214 subsequent to depositing and planarizing a mask material 112 on the assembly 212 (FIG. 8). The mask material 112 may include any suitable dielectric material, and in some embodiments, could include multiple layers of mask material having desired material compositions are properties. The mask material 112 may be deposited so that it is present over and between the spacers 111, as shown.

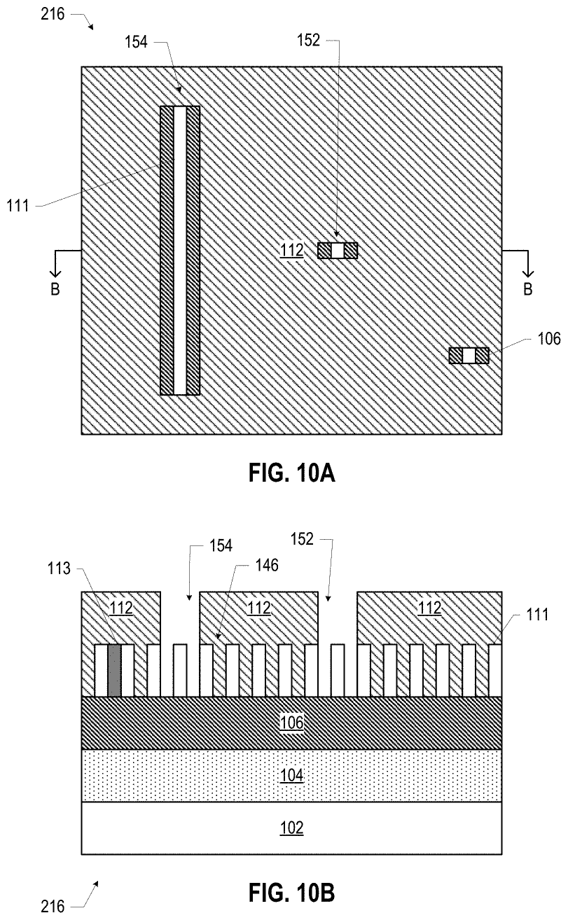

FIG. 10 depicts an assembly 216 subsequent to forming cavities in the mask material 112 of the assembly 214 (FIG. 9). These cavities may extend down to the hardmask 106, and may selectively expose portions of the second spacers 111. For example, FIG. 10 depicts an elongate cavity 154 that exposes an elongate section of the second spacers 111, as well as smaller cavities 152 that expose shorter sections of the second spacers 111. As will be demonstrated below, the location of the cavities in the assembly 216 generally correspond to locations of the conductive lines 116 in the patterned line region 120, with the elongate cavity 154 corresponding to the wide line 1168 and the smaller cavities 152 corresponding to the bridges 118. Cavities may be formed in the mask material 112 using photolithography, and may be sized and arranged as desired.

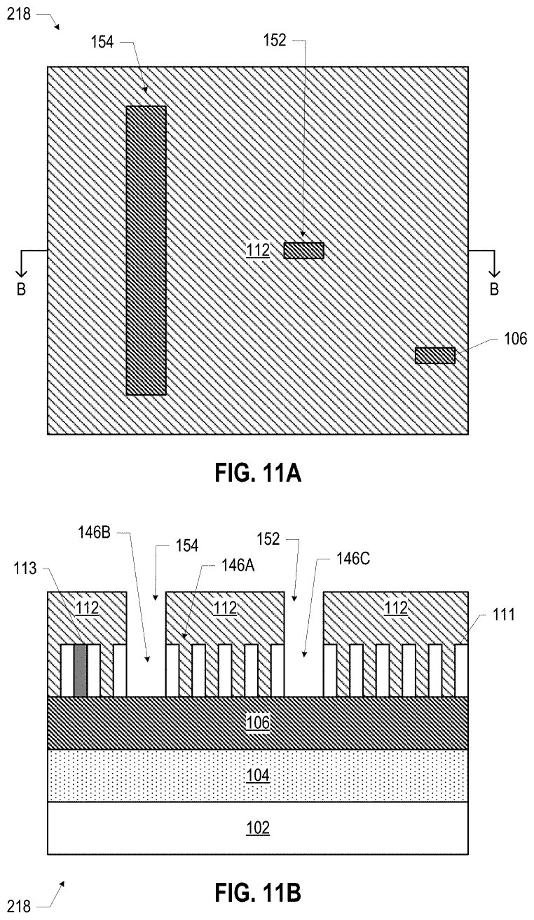

FIG. 11 depicts an assembly 218 subsequent to removing the second spacers 111 that are not covered by the mask material 112 in the assembly 216 (FIG. 10). A suitable selective etch may be used to remove these “exposed” second spacers 111. The assembly 218 may include narrow trenches 146A between portions of the second spacers 111 (which will correspond to the narrow lines 116A) and wide trenches 1468 between portions of the second spacers 111 (which will correspond to the wide lines 1168). The assembly 218 may also include trenches 146C between portions of the second spacers 111, which will correspond to the bridges 118.

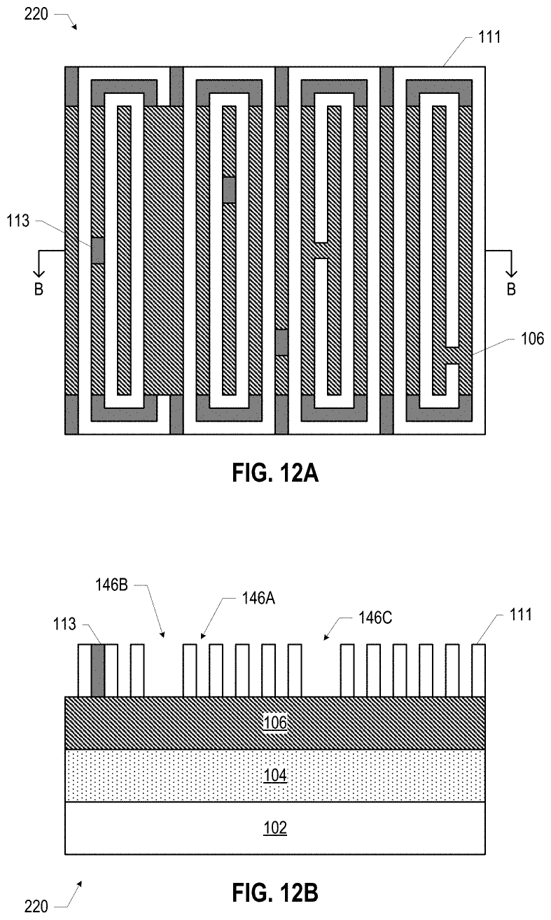

FIG. 12 depicts an assembly 220 subsequent to removing the mask material 112 from the assembly 218 (FIG. 11). A suitable selective etch may be used to remove the mask material 112. FIG. 12

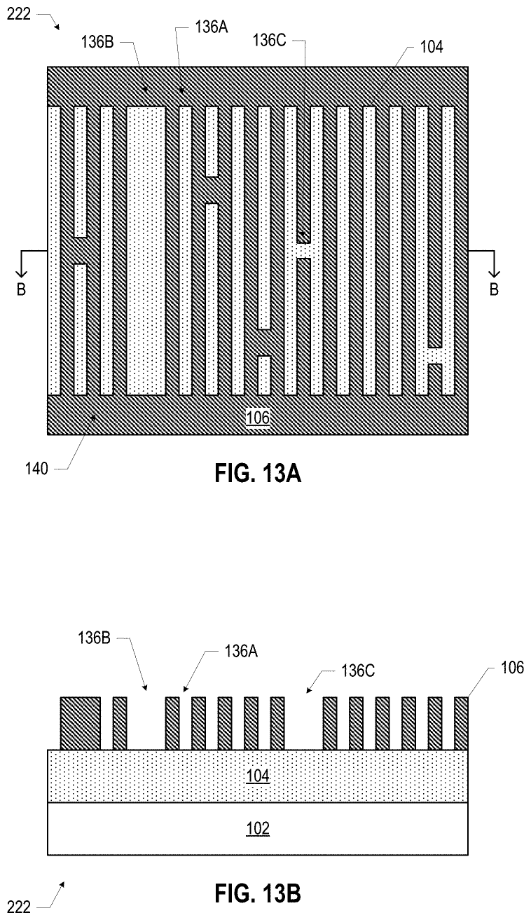

FIG. 13 depicts an assembly 222 subsequent to patterning the hardmask 106 in accordance with the pattern of the second spacers 111 of the assembly 220 (FIG. 12), and then removing the second spacers 111. The portions of hardmask 106 that remain after patterning correspond to the portions of the second spacers 111 in the assembly 220, and thus FIG. 13 reflects the transfer of the pattern of the second spacers 111 in the assembly 220 to the hardmask 106. Any suitable selective etch techniques may be used to transfer the pattern of the second spacers 111 to the hardmask 106, and then remove the second spacers 111. The assembly 222 may include narrow trenches 136A between portions of the hardmask 106 (which will correspond to the narrow lines 116A) and wide trenches 1368 between portions of the hardmask 106 (which will correspond to the wide lines 1168). The assembly 222 may also include trenches 136C between portions of the hardmask 106, which will correspond to the bridges 118.

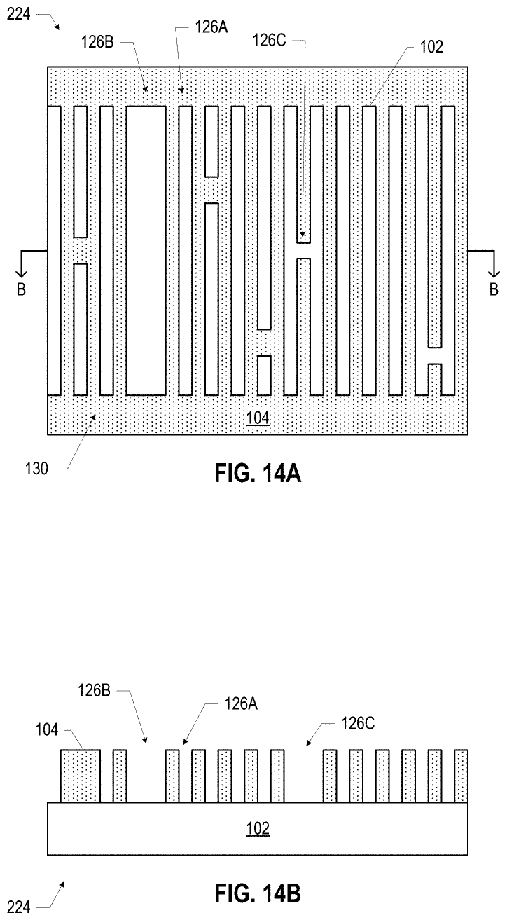

FIG. 14 depicts an assembly 224 subsequent to patterning the dielectric material 104 in accordance with the pattern of the hardmask 106 of the assembly 222 (FIG. 13), and then removing the hardmask 106. The portions of dielectric material 104 that remain after patterning correspond to the portions of the hardmask 106 in the assembly 222, and thus FIG. 14 reflects the transfer of the pattern of the hardmask 106 in the assembly 222 to the dielectric material 104. Any suitable selective etch techniques may be used to transfer the pattern of the hardmask 106 to the dielectric material 104, and then remove the hardmask 106. The assembly 224 may include narrow trenches 126A between portions of the dielectric material 104 (which will correspond to the narrow lines 116A) and wide trenches 1268 between portions of the dielectric material 104 (which will correspond to the wide lines 1168). The assembly 224 may also include trenches 126C between portions of the dielectric material 104, which will correspond to the bridges 118.

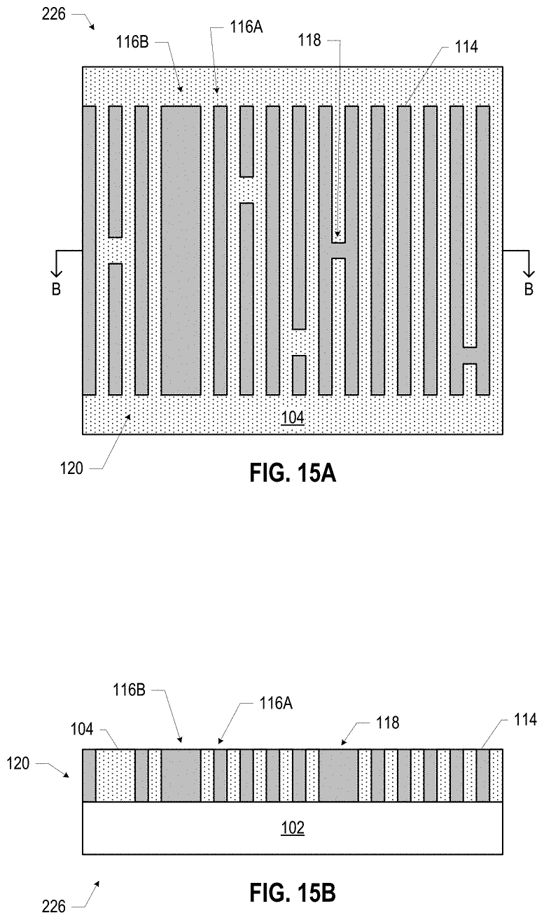

FIG. 15 depicts an assembly 226 subsequent to providing material(s) 114 in the trenches 126 of the assembly 224 (FIG. 14) to form conductive lines 116 and bridges 118. The assembly 226 may take the form of the IC structure 100 of FIG. 1. Further processing may then be performed; for example, further interconnect layers of a metallization stack (e.g., a metallization stack 1619, discussed below with reference to FIG. 18) may be fabricated on the assembly 226, including conductive lines and/or vias in electrical contact with the lines 116.

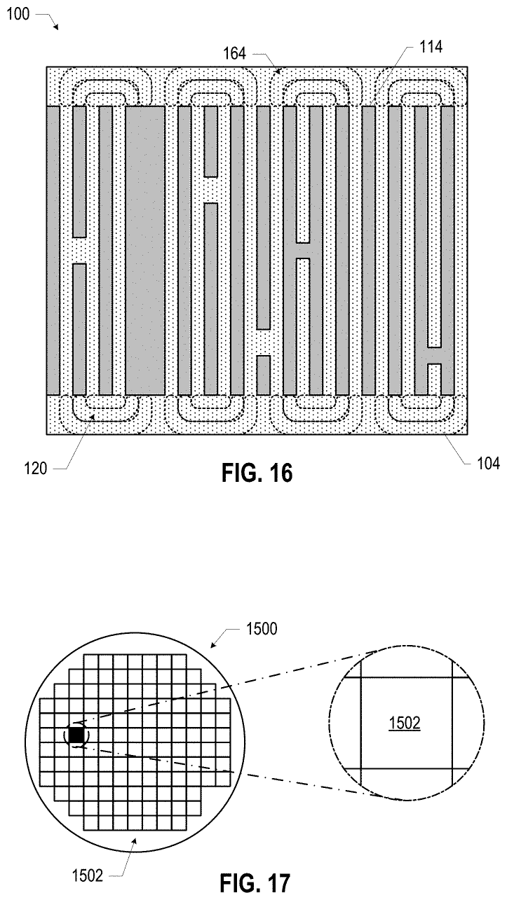

The fabrication process discussed above with reference to FIGS. 2-15 includes a pitch-division technique corresponding to FIGS. 1-7. The particular pitch-division technique of FIGS. 1-7 is a pitch-quartering technique (utilizing two rounds of spacer formation), but in other embodiments, a pitch-halving technique (using a single round of spacer formation) may be used instead (at a penalty of larger feature size). The use of such pitch-division techniques in the process of forming a patterned line region 120 may be evidenced in an IC device 100 by the presence of pitch-division artifacts in the IC device 100. For example, because of the manner in which the dimensions 156, 158, 160, and 162 propagate through the pitch-division technique to the widths 122 and inter-line spacings 125, the widths 122 and the inter-line spacings 125 may exhibit a periodicity across multiple ones of the lines 116. Such periodicity may serve as a pitch-division artifact in the IC device 100 that provides evidence of the use of a pitch-division technique during fabrication. Another example of a pitch-division artifact that may appear in the IC device 100 are nested and/or rounded, half-ring patterns in the dielectric material 104 that correspond to the shorter ends of the second spacers 111 in the assembly 220 of FIG. 12. FIG. 16 is a top view of the IC device 100 illustrating such nested and rounded patterns 164 proximate to a perimeter of the patterned line region 120; in embodiments in which a pitch-halving technique is used instead of a pitch-quartering technique, fewer “half-rings” may be part of the patterns 164. The presence of such nested and/or rounded patterns may serve as a pitch-division artifact in the IC device 100 that provides evidence of the use of the pitch-division technique during fabrication. Other pitch-division artifacts may be present instead of or in addition to one or more of these artifacts. For example, spacer-based pitch division, as discussed above, may have a single size of a feature (either a line width or a width of a space between lines) that is defined by ALD spacer deposition. The thickness of the ALD spacer deposition determines this size.

The patterned line regions 120 disclosed herein may be included in any suitable electronic component. FIGS. 17-21 illustrate various examples of apparatuses that may include any of the patterned line regions 120 disclosed herein, or may be included in an IC package that also includes any of the patterned line regions 120 disclosed herein.

FIG. 17 is a top view of a wafer 1500 and dies 1502 that may include one or more patterned line regions 120, or may be included in an IC package including one or more patterned line regions 120 (e.g., as discussed below with reference to FIG. 19) in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more patterned line regions 120 (e.g., as discussed below with reference to FIG. 18), one or more transistors (e.g., some of the transistors 1640 of FIG. 18, discussed below) and/or supporting circuitry to route electrical signals to the transistors, as well as any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 21) or other logic that is configured to store information in the memory devices or execute instructions stored in the memory array.

FIG. 18 is a side, cross-sectional view of an IC device 1600 that may include one or more patterned line regions 120, or may be included in an IC package including one or more patterned line regions 120 (e.g., as discussed below with reference to FIG. 19), in accordance with any of the embodiments disclosed herein. One or more of the IC devices 1600 may be included in one or more dies 1502 (FIG. 17). The IC device 1600 may be formed on a substrate 1602 (e.g., the wafer 1500 of FIG. 17) and may be included in a die (e.g., the die 1502 of FIG. 17). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 17) or a wafer (e.g., the wafer 1500 of FIG. 17).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 18 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 18 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600. In some embodiments, one or more patterned line regions 120 may be disposed in one or more of the interconnect layers 1606-1610, in accordance with any of the techniques disclosed herein. FIG. 18 illustrates a single patterned line region 120 in the interconnect layer 1606 for illustration purposes, but any number and structure of patterned line regions 120 may be included in any one or more of the layers in a metallization stack 1619. One or more patterned line regions 120 in the metallization stack 1619 may be coupled to any suitable ones of the devices in the device layer 1604, and/or to one or more of the conductive contacts 1636 (discussed below).

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 18). Although a particular number of interconnect layers 1606-1610 is depicted in FIG. 18, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 18; some or all of the lines 1628a may be lines 116 in a patterned line region 120 in accordance with any of the embodiments disclosed herein. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 18. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604. In some embodiments, this first interconnect layer 1606 may be an “MO” layer; the use of the patterned line regions 120 disclosed herein may be particularly advantageous in the first interconnect layer 1606, but may be used in any interconnect layer in a metallization stack 1619.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 18, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

FIG. 19 is a side, cross-sectional view of an example IC package 1650 that may include one or more XXX. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects 1628 discussed above with reference to FIG. 18.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 or to the XXX (or to other devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 19 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., (e.g., a silicon bridge, an organic bridge, one or more waveguides, one or more interposers, wirebonds, etc.). In some embodiments, an interposer 1657 may include one or more patterned line regions 120 in accordance with any of the embodiments disclosed herein.

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 19 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

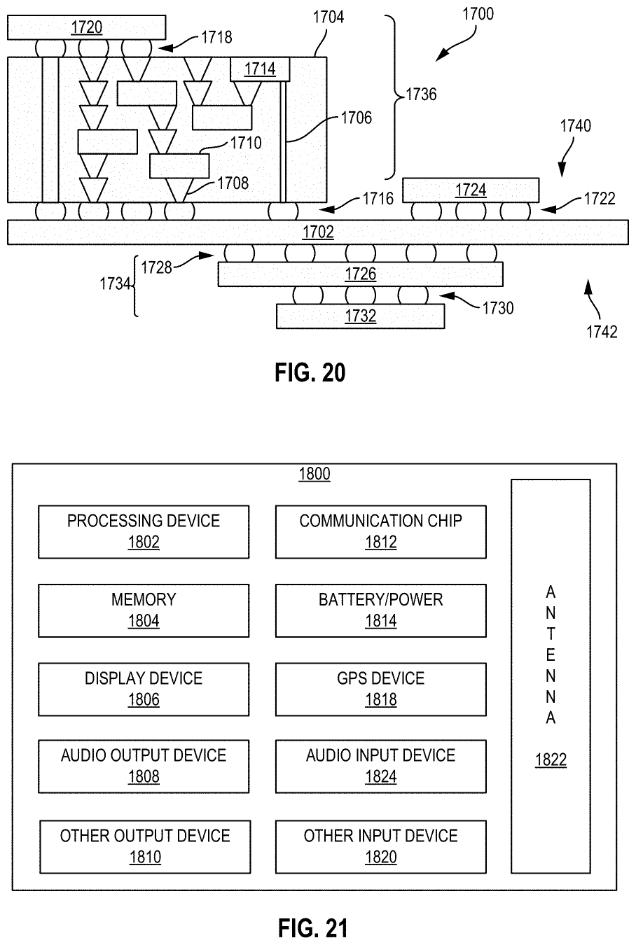

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 19 are solder balls (e.g., for a ball grid array arrangement), but any suitable second-level interconnects 16770 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 20.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory). In some embodiments, the die 1656 may include one or more patterned line regions 120 (e.g., as discussed above with reference to FIG. 17 and FIG. 18); in other embodiments, the die 1656 may not include any patterned line regions 120

Although the IC package 1650 illustrated in FIG. 19 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 19, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 20 is a side, cross-sectional view of an IC device assembly 1700 that may include one or more IC packages or other electronic components (e.g., a die) including one or more patterned line regions 120, in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 19 (e.g., may include one or more XXX in a package substrate 1652 or in a die).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 20 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 20), male and female portions of a socket, an adhesive, an underfill material, and/or any other suitable electrical and/or mechanical coupling structure.

The package-on-interposer structure 1736 may include an IC package 1720 coupled to an package interposer 1704 by coupling components 1718. The coupling components 1718 may take any suitable form for the application, such as the forms discussed above with reference to the coupling components 1716. Although a single IC package 1720 is shown in FIG. 20, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 17), an IC device (e.g., the IC device 1600 of FIG. 18), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 20, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art. In some embodiments, the package interposer 1704 may include one or more patterned line regions 120

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 20 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 21 is a block diagram of an example electrical device 1800 that may include one or more patterned line regions 120, in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 21 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 21, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is an integrated circuit (IC) device, including a patterned line region, including a first conductive line, a second conductive line parallel to the first conductive line, a conductive bridge between the first conductive line and the second conductive line, wherein the conductive bridge is coplanar with the first conductive line and the second conductive line, and pitch-division artifacts proximate to a perimeter of the patterned line region.

Example 2 includes the subject matter of Example 1, and further specifies that the first conductive line has a width that is less than 20 nanometers.

Example 3 includes the subject matter of any of Examples 1-2, and further specifies that a distance between the first conductive line and the second conductive line is less than 20 nanometers.

Example 4 includes the subject matter of any of Examples 1-3, and further specifies that the patterned line region is included in an MO interconnect layer.

Example 5 includes the subject matter of any of Examples 1-4, and further specifies that the conductive bridge is perpendicular to the first conductive line.

Example 6 includes the subject matter of any of Examples 1-5, and further specifies that the conductive bridge has a same height as the first conductive line and the second conductive line.

Example 7 includes the subject matter of any of Examples 1-6, and further includes: a dielectric material coplanar with the first conductive line and the second conductive line.

Example 8 includes the subject matter of Example 7, and further specifies that the pitch-division artifacts include one or more half-ring patterns in the dielectric material.

Example 9 includes the subject matter of any of Examples 1-8, and further specifies that the pitch-division artifacts include widths of at least some conductive lines in the patterned line region being periodic across the conductive lines.

Example 10 includes the subject matter of any of Examples 1-9, and further specifies that a pitch from the first conductive line to the second conductive line is 40 nanometers or less.

Example 11 includes the subject matter of any of Examples 1-10, and further specifies that the patterned line region further includes: a third conductive line; and a fourth conductive line adjacent to and parallel with the third conductive line, wherein the fourth conductive line has a width that is at least three times greater than a width of the third conductive line.

Example 12 includes the subject matter of Example 11, and further specifies that a pitch from the third conductive line to the fourth conductive line is 40 nanometers or less.

Example 13 includes the subject matter of any of Examples 11-12, and further specifies that the third conductive line has a width that is less than 20 nanometers.

Example 14 includes the subject matter of any of Examples 11-13, and further specifies that a distance between the third conductive line and the fourth conductive line is less than 20 nanometers.

Example 15 includes the subject matter of any of Examples 1-14, and further includes: a device layer; wherein the patterned line region is included in an interconnect layer above or below the device layer.

Example 16 includes the subject matter of Example 15, and further includes: conductive contacts, wherein the patterned line region is between the conductive contacts and the device layer.

Example 17 is an integrated circuit (IC) device, including a patterned line region, including a first conductive line, a second conductive line adjacent to and parallel with the first conductive line, wherein the second conductive line has a width that is at least three times greater than a width of the first conductive line, and pitch-division artifacts.

Example 18 includes the subject matter of Example 17, and further specifies that a pitch from the first conductive line to the second conductive line is 40 nanometers or less.

Example 19 includes the subject matter of any of Examples 17-18, and further specifies that the first conductive line has a width that is less than 20 nanometers.

Example 20 includes the subject matter of any of Examples 17-19, and further specifies that a distance between the first conductive line and the second conductive line is less than 20 nanometers.

Example 21 includes the subject matter of any of Examples 17-20, and further specifies that the patterned line region is included in an MO interconnect layer.

Example 22 includes the subject matter of any of Examples 17-21, and further includes: a dielectric material coplanar with the first conductive line and the second conductive line.

Example 23 includes the subject matter of Example 22, and further specifies that the pitch-division artifacts include one or more half-ring patterns in the dielectric material.

Example 24 includes the subject matter of any of Examples 17-23, and further specifies that the pitch-division artifacts includes widths of at least some conductive lines in the patterned line region being periodic across the conductive lines.

Example 25 includes the subject matter of any of Examples 17-24, and further specifies that the patterned line region further includes: a third conductive line; a fourth conductive line parallel to the third conductive line, and a conductive bridge between the third conductive line and the fourth conductive line, wherein the conductive bridge is coplanar with the third conductive line and the fourth conductive line.

Example 26 includes the subject matter of Example 25, and further specifies that a pitch from the third conductive line to the fourth conductive line is 40 nanometers or less.

Example 27 includes the subject matter of any of Examples 25-26, and further specifies that the third conductive line has a width that is less than 20 nanometers.

Example 28 includes the subject matter of any of Examples 25-27, and further specifies that a distance between the third conductive line and the fourth conductive line is less than 20 nanometers.

Example 29 includes the subject matter of any of Examples 25-28, and further specifies that the conductive bridge is perpendicular to the first conductive line.

Example 30 includes the subject matter of any of Examples 25-29, and further specifies that the conductive bridge has a same height as the first conductive line and the second conductive line.

Example 31 includes the subject matter of any of Examples 17-30, and further includes: a device layer; wherein the patterned line region is included in an interconnect layer above or below the device layer.

Example 32 includes the subject matter of Example 31, and further includes: conductive contacts, wherein the patterned line region is between the conductive contacts and the device layer.

Example 33 is a computing device, including: a die, wherein the die includes an interconnect layer in which a conductive bridge couples two adjacent pitch-divided conductive lines; and a circuit board, wherein the die is electrically coupled to the circuit board.

Example 34 includes the subject matter of Example 33, and further specifies that the conductive lines have a width that is less than 20 nanometers.

Example 35 includes the subject matter of any of Examples 33-34, and further specifies that a distance between the conductive lines is less than 20 nanometers.

Example 36 includes the subject matter of any of Examples 33-35, and further specifies that the interconnect layer is an MO interconnect layer.

Example 37 includes the subject matter of any of Examples 33-36, and further specifies that the conductive bridge is perpendicular to the conductive lines.

Example 38 includes the subject matter of any of Examples 33-37, and further specifies that the conductive bridge has a same height as the conductive lines.

Example 39 includes the subject matter of any of Examples 33-38, and further specifies that the die further includes: a dielectric material coplanar with the conductive lines.

Example 40 includes the subject matter of Example 39, and further specifies that the die further includes: one or more half-ring patterns in the dielectric material.

Example 41 includes the subject matter of any of Examples 33-40, and further specifies that widths of at least some conductive lines in the interconnect layer are periodic across the at least some conductive lines.

Example 42 includes the subject matter of any of Examples 33-41, and further specifies that the die is included in a package, and the package is coupled to the circuit board.

Example 43 includes the subject matter of any of Examples 33-42, and further specifies that the circuit board is a motherboard.

Example 44 includes the subject matter of any of Examples 33-43, and further specifies that the die is part of a processing device or a memory device.

Example 45 includes the subject matter of any of Examples 33-44, and further specifies that the computing device is a mobile computing device.

Example 46 is a computing device, including: a die, wherein the die includes an interconnect layer in which a pitch-divided conductive line is adjacent to a conductive line having a width that is at least three times greater than a width of the pitch-divided conductive line; and a circuit board, wherein the die is electrically coupled to the circuit board.

Example 47 includes the subject matter of Example 46, and further specifies that a distance between the conductive lines is less than 20 nanometers.

Example 48 includes the subject matter of any of Examples 46-47, and further specifies that the interconnect layer is an MO interconnect layer.

Example 49 includes the subject matter of any of Examples 46-48, and further specifies that the die further includes: a dielectric material coplanar with the conductive lines.

Example 50 includes the subject matter of Example 49, and further specifies that the die further includes: one or more half-ring patterns in the dielectric material.

Example 51 includes the subject matter of any of Examples 46-50, and further specifies that widths of at least some conductive lines in the interconnect layer are periodic across the at least some conductive lines.

Example 52 includes the subject matter of any of Examples 46-51, and further specifies that the die is included in a package, and the package is coupled to the circuit board.

Example 53 includes the subject matter of any of Examples 46-52, and further specifies that the circuit board is a motherboard.

Example 54 includes the subject matter of any of Examples 46-53, and further specifies that the die is part of a processing device or a memory device.

Example 55 includes the subject matter of any of Examples 46-54, and further specifies that the computing device is a mobile computing device.

Example 56 includes the subject matter of any of Examples 46-55, and further specifies that the pitch-divided conductive line has a width that is less than 20 nanometers.

1. An integrated circuit (IC) device, comprising:
a patterned line region, including:
a first conductive line,
a second conductive line parallel to the first conductive line,
a conductive bridge between the first conductive line and the second conductive line, wherein the conductive bridge is coplanar with the first conductive line and the second conductive line, and
pitch-division artifacts proximate to a perimeter of the patterned line region.

2. The IC device of claim 1, wherein the first conductive line has a width that is less than 20 nanometers.

3. The IC device of claim 1, wherein a distance between the first conductive line and the second conductive line is less than 20 nanometers.

4. The IC device of claim 1, further comprising:
a dielectric material coplanar with the first conductive line and the second conductive line.

5. The IC device of claim 4, wherein the pitch-division artifacts include one or more half-ring patterns in the dielectric material.

6. The IC device of claim 1, wherein the patterned line region further includes:
a third conductive line; and
a fourth conductive line adjacent to and parallel with the third conductive line, wherein the fourth conductive line has a width that is at least three times greater than a width of the third conductive line.

7. The IC device of claim 1, further comprising:
a device layer;
wherein the patterned line region is included in an interconnect layer above or below the device layer.

8. The IC device of claim 7, further comprising:
conductive contacts, wherein the patterned line region is between the conductive contacts and the device layer.

9. An integrated circuit (IC) device, comprising:
a patterned line region, including:
a first conductive line,
a second conductive line adjacent to and parallel with the first conductive line, wherein the second conductive line has a width that is at least three times greater than a width of the first conductive line, and
pitch-division artifacts.

10. The IC device of claim 9, wherein the pitch-division artifacts include widths of at least some conductive lines in the patterned line region being periodic across the conductive lines.

11. The IC device of claim 9, wherein the patterned line region further includes:
a third conductive line;
a fourth conductive line parallel to the third conductive line, and
a conductive bridge between the third conductive line and the fourth conductive line, wherein the conductive bridge is coplanar with the third conductive line and the fourth conductive line.

12. The IC device of claim 11, wherein a pitch from the third conductive line to the fourth conductive line is 40 nanometers or less.

13. The IC device of claim 11, wherein the third conductive line has a width that is less than 20 nanometers.

14. The IC device of claim 11, wherein a distance between the third conductive line and the fourth conductive line is less than 20 nanometers.

15. The IC device of claim 11, wherein the conductive bridge is perpendicular to the first conductive line.

16. The IC device of claim 11, wherein the conductive bridge has a same height as the first conductive line and the second conductive line.

17. A computing device, comprising:
a die, wherein the die includes an interconnect layer in which a conductive bridge couples two adjacent pitch-divided conductive lines; and
a circuit board, wherein the die is electrically coupled to the circuit board.

18. The computing device of claim 17, wherein the die is included in a package, and the package is coupled to the circuit board.

19. The computing device of claim 17, wherein the circuit board is a motherboard.

20. The computing device of claim 17, wherein the die is part of a processing device or a memory device.
